(19) United States
(12) Patent Application Publication
(10) Pub. No.: US 2009/0215274 A1
(43) Pub. Date: Aug. 27, 2009

(54) Plasma processing apparatus and plasma processing method

(75) Inventors: Naoki Matsumoto, Hyogo (JP); Jun Yoshikawa, Hyogo (JP); Tetsuya Nishizuka, Hyogo (JP); Masaru Sasaki, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/392,228

(22) Filed: Feb. 25, 2009

(30) Foreign Application Priority Data
Feb. 26, 2008 (JP) 2008-045023

(51) Int. Cl. H01L 21/3065; C23C 16/54; H01L 21/283

(52) U.S. Cl. 438/726; 118/723 MW; 156/345.41; 438/758; 257/E21.218; 257/E21.159

(57) ABSTRACT

The plasma processing apparatus includes a holding table disposed in a processing chamber, for holding thereon a target substrate; a dielectric plate disposed at a position facing the holding table, for introducing a microwave into the processing chamber; a plasma igniting unit for carrying out plasma ignition in a state in which an electric field is generated inside the processing chamber by the introduced microwave, thereby generating the plasma inside the processing chamber; and a control unit, which includes an elevating mechanism, for performing control operations to alter a distance between the holding table and the dielectric plate to a first distance, to drive the plasma igniting unit, to alter the distance between the holding table and the dielectric plate to a second distance different from the first distance, and to carry out the plasma process on the semiconductor substrate.

### FIELD OF THE INVENTION

The present disclosure relates to a plasma processing apparatus and method; and, more particularly, to a plasma processing apparatus and method for generating plasma by using a microwave as a plasma source.

### BACKGROUND OF THE INVENTION

A semiconductor device such as a LSI (Large Scale Integrated Circuit) or the like is manufactured by performing a plurality of processes such as etching, CVD (Chemical Vapor Deposition), sputtering, and so forth on a semiconductor substrate (wafer) which is a target substrate to be processed. As for such processes as etching, CVD and sputtering, there is known a processing method of using plasma as an energy supply source. That is, there are known processing methods such as plasma etching, plasma CVD, plasma sputtering, and the like.

Here, a plasma processing apparatus using a microwave as a plasma generating source is disclosed in Japanese Patent Laid-open Publication No. 2005-100931 (Patent Document 1). According to the Patent Document 1, a tapered protruding portion or recess portion is formed on the bottom surface of a top plate (dielectric plate) installed in the plasma processing apparatus. An optimal resonance region of electric field is formed at the tapered protruding portion or recess portion on the bottom surface of the top plate by means of a microwave generated by a microwave generator, and stable plasma is generated in a chamber (processing vessel), whereby the aforementioned etching process or the like is performed.
Patent Document 1: Japanese Patent Laid-open Publication No. 2005-100931

In the plasma processing apparatus using the microwave as a plasma source, the introduced microwave forms a standing wave in the thickness direction of the dielectric plate, and by this standing wave, an electric field is generated inside the processing chamber, specifically, under the dielectric plate in the processing chamber. Here, a plasma igniting condition by the microwave, i.e., an application power for igniting the plasma or the like may be differed depending on electric field intensity inside the processing apparatus. The level of the electric field intensity varies depending on a distance between a holding table for holding the target substrate to be processed thereon and the dielectric plate. Here, in case that the holding table is fixed as in the Patent Document 1, even if plasma could be generated by setting up a certain plasma igniting condition under a preset condition, the electric field intensity inside the processing chamber would be changed under a condition different from the preset condition, for example, if a pressure inside the processing chamber is changed. In such case, there is a concern that plasma generation under the aforementioned certain plasma igniting condition cannot be achieved.

Meanwhile, the distance between the dielectric plate and the holding table suitable for generating the plasma is not always coincident with the distance between the dielectric plate and the holding table suitable for performing the plasma process. In this regard, it may not be reasonable to perform the plasma process under the plasma igniting condition all the time.

### BRIEF SUMMARY OF THE INVENTION

In view of the foregoing, the present disclosure provides a plasma processing apparatus capable of performing a plasma process appropriately, while improving plasma ignition property.

The present disclosure also provides a plasma processing method capable of performing a plasma process appropriately, while improving plasma ignition property.

In accordance with one aspect of the present invention, there is provided a plasma processing apparatus including: a processing chamber for performing therein a plasma process on a target substrate to be processed; a reactant gas supply unit for supplying a reactant gas for the plasma process into the processing chamber; a holding table disposed in the processing chamber, for holding thereon the target substrate; a microwave generator for generating a microwave for plasma excitation; a dielectric plate disposed at a position facing the holding table, for introducing the microwave into the processing chamber; a plasma igniting unit for carrying out plasma ignition in a state where an electric filed is generated inside the processing chamber by the introduced microwave, and then generating plasma within the processing chamber; and a control unit for performing control operations to alter a distance between the holding table and the dielectric plate to a first distance, to drive the plasma igniting unit, to alter the distance between the holding table and the dielectric plate to a second distance different from the first distance, and to carry out the plasma process on the target substrate.

By using this plasma processing apparatus, it is possible to perform the plasma ignition by setting the distance between the holding table and the dielectric plate to the first distance. By doing this, the plasma ignition can be easily carried out by selecting the distance at which electric field intensity increases as the first distance, so that plasma ignition property can be improved. Further, during the plasma process of the target substrate, the distance between the holding table and the dielectric plate is set to the second distance, which is appropriate for the plasma process, so that the plasma process of the target substrate can be carried out appropriately. As a result, the plasma ignition property can be improved, and the plasma process can be performed properly.

It is desirable that the control unit includes an elevating mechanism for altering the distance between the holding table and the dielectric plate by moving the holding table up and down.

It is more desirable that the control unit varies the first distance based on periodicity of a standing wave formed in the dielectric plate by the introduction of the microwave.

Further, the reactant gas supply unit may supply the reactant gas having dissociation property, and the control unit may make the second distance shorter than the first distance.

It is desirable that the plasma process performed on the target substrate by the control unit is an etching process for an oxide-based film.

Further, the reactant gas supply unit may supply the reactant gas not having dissociation property, and the control unit may make the second distance longer than the first distance.

Desirably, the plasma process performed on the target substrate by the control unit is an etching process for a polysilicon-based film.

In accordance with the other aspect of the present invention, there is provided a plasma processing method for performing a plasma process on a target substrate to be processed, the method including: holding the target substrate on a holding table installed in a processing chamber; generating a microwave for plasma excitation; generating an electric field in the processing chamber by introducing the microwave into the processing chamber via a dielectric plate disposed at a position facing the holding table; generating plasma in the processing chamber by igniting the plasma in a state where a distance between the holding table and the dielectric plate is set to a first distance and an electric field is generated in the processing chamber; and setting the distance between the holding table and the dielectric plate to a second distance different from the first distance after generating the plasma and performing the plasma process on the target substrate.

By employing this plasma processing method, it is possible to perform the plasma ignition by setting the distance between the holding table and the dielectric plate to the first distance. By doing this, the plasma ignition can be carried out by selecting the distance at which the electric field intensity increases as the first distance, so that plasma ignition property can be improved. Further, during the plasma process of the target substrate, the distance between the holding table and the dielectric plate is set to the second distance, which is appropriate for the plasma process, so that the plasma process can be carried out appropriately. As a result, the plasma excitation property can be improved, and the plasma process can be performed properly.

By using the above-stated plasma processing apparatus and plasma processing method, it is possible to perform the plasma ignition by setting the distance between the holding table and the dielectric plate to the first distance. By doing this, the plasma ignition can be carried out by selecting the distance at which the electric field intensity increases as the first distance, so that plasma ignition property can be improved. Further, during the plasma process of the target substrate, the distance between the holding table and the dielectric plate is set to the second distance, which is appropriate for the plasma process, so that the plasma process can be carried out appropriately. As a result, the plasma ignition property can be improved, and the plasma process can be performed properly.

### BRIEF DESCRIPTION OF THE DRAWINGS

The disclosure may best be understood by reference to the following description taken in conjunction with the following figures:

FIG. 1 provides a schematic cross sectional view showing major components of a plasma processing apparatus in accordance with an embodiment of the present invention;

FIG. 2 sets forth a diagram illustrating a state of the plasma processing apparatus shown in FIG. 1, in which a gap is narrowed;

FIG. 3 presents a diagram illustrating a state of the plasma processing apparatus shown in FIG. 1, in which the gap is enlarged;

FIG. 4 depicts a graph showing a relationship between electric field intensity and the gap;

FIG. 5 offers a graph showing a relationship between the gap and a microwave power necessary for plasma ignition;

FIG. 6 is a schematic view illustrating an electric field state under a dielectric plate in case that the gap is set to about 145 mm;

FIG. 7 is a schematic view illustrating an electric field state under the dielectric plate in case that the gap is set to about 144 mm;

FIG. 8 is a schematic view illustrating an electric field state under the dielectric plate in case that the gap is set to about 142 mm;

FIG. 9 is a schematic view illustrating an electric field state under the dielectric plate in case that the gap is set to about 140 mm;

FIG. 10 is a schematic view illustrating an electric field state under the dielectric plate in case that the gap is set to about 135 mm;

FIG. 11 is a schematic view illustrating an electric field state under the dielectric plate in case that the gap is set to about 205 mm;

FIG. 12 is a schematic view illustrating an electric field state under the dielectric plate in case that the gap is set to about 245 mm;

FIG. 13 sets forth a diagram showing measurement directions for etching rate;

FIG. 14 provides an electronography of a part of a semiconductor substrate on which an etching process has been performed after setting the gap to about 135 mm; and

FIG. 15 presents an electronography of a part of a semiconductor substrate on which an etching process has been performed after setting the gap to about 245 mm.

### DETAILED DESCRIPTION OF THE INVENTION

Hereinafter, embodiments of the present invention will be described in detail with reference to the accompanying drawings.

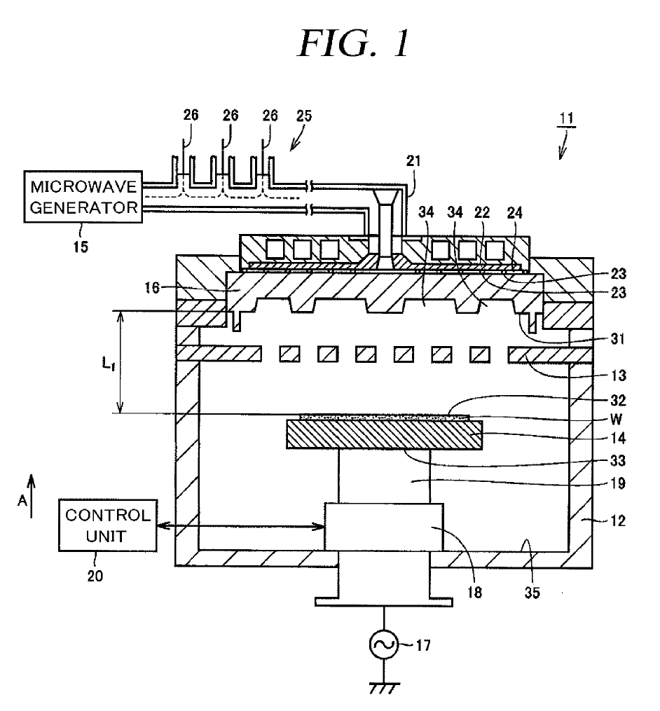

FIG. 1 is a schematic cross sectional view showing major components of a plasma processing apparatus in accordance with an embodiment of the present invention. In the following drawings, an upside of the paper is assumed as upper direction.

Referring to FIG. 1, the plasma processing apparatus 11 includes a processing chamber 12 for performing therein a plasma process on a semiconductor substrate W which is a target substrate to be processed; a gas shower head 13 serving as a reactant gas supply unit for supplying a reactant gas for the plasma process into the processing chamber 12 from an opening portion; a holding table 14 of a circular plate shape disposed in the processing chamber 12, for holding thereon the semiconductor substrate W; a microwave generator 15 for generating a microwave for plasma excitation; a dielectric plate 16 disposed at a position facing the holding table 14, for introducing the microwave generated by the microwave generator 15 into the processing chamber 12; when an electric field is generated in the processing chamber 12 by the microwave introduced therein, a plasma ignition unit (not shown) for igniting the plasma by applying a preset power to generate plasma in the processing chamber 12; and a control unit 20 for controlling the entire plasma processing apparatus 11. The control unit 20 controls processing conditions for processing the semiconductor substrate W such as a gas flow rate in the gas shower head 13, an internal pressure of the processing chamber 12, and the like.

The plasma processing apparatus 11 includes a vacuum pump (not shown), a gas exhaust pipe (not shown), and so forth, and is capable of setting the internal pressure of the processing chamber 12 to a preset pressure level such as a vacuum by depressurizing the processing chamber 2. The top portion of the processing chamber 12 is opened, and the processing chamber 12 is configured to be hermetically sealed by a sealing member (not shown) and the dielectric plate 16 disposed at the top portion of the processing chamber 12.

The dielectric plate 16 has a circular plate shape and is made of a dielectric material. The dielectric plate 16 is provided with a plurality of annular recess portions 34 depressed in tapered shapes on its bottom portion.

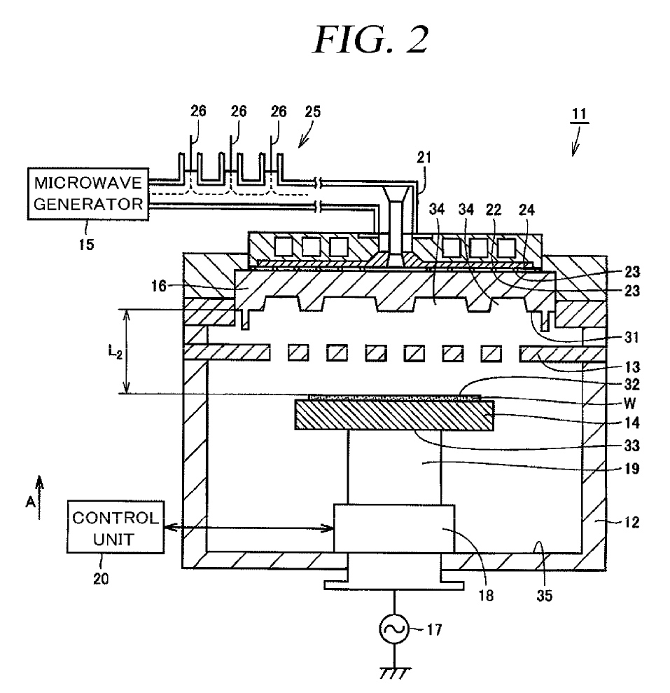

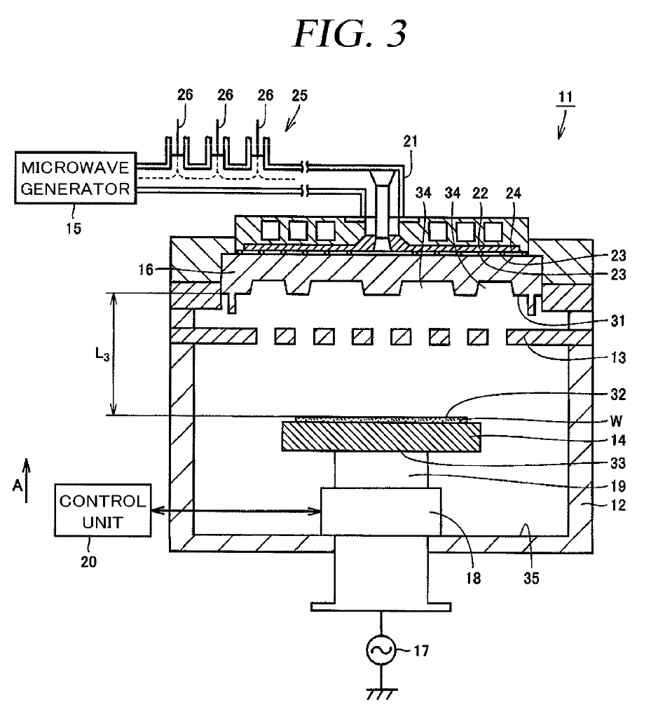

The plasma processing apparatus 11 is equipped with an elevating mechanism 18 serving as an elevating unit for elevating the holding table 14. The elevating mechanism 18 elevates the holding table 14 by moving a supporting column 19 installed at a bottom surface 33 of the holding table 14 up and down. By elevating the holding table 14 within a predetermined spatial range by means of the elevating mechanism 18, the distance between the holding table 14 and the dielectric plate 16 fixed by the processing chamber 12 or the like can be varied. Specifically, a distance L₁ between the top surface 32 of the semiconductor substrate W held on the holding table 14 and the bottom surface 31 of the dielectric plate 16 can be altered. FIG. 2 illustrates a state in which a distance L₂ is set up by decreasing the distance between the top surface 32 of the semiconductor substrate W and the bottom surface 31 of the dielectric plate 16 by way of raising the holding table 14 from the state shown in FIG. 1 by means of the elevating mechanism 18, whereas FIG. 3 illustrates a state in which a distance L₃ is set up by increasing the distance between the top surface 32 of the semiconductor substrate W and the bottom surface 31 of the dielectric plate 16 by way of lowering the holding table 14 from the state shown in FIG. 1 by means of the elevating mechanism 18. Here, the bottom surface 31 of the dielectric plate 16 refers to a surface of its flat portion where no recess portion 34 is provided.

The microwave generator 15 is made up of a high frequency power supply (not shown) and the like. Also connected to the holding table 14 is a high frequency power supply for supplying a bias voltage thereto. Further, installed inside the holding table 14 is a non-illustrated heater for heating the semiconductor substrate W up to a preset temperature condition during the plasma process.

The plasma processing apparatus 11 also includes a waveguide 21 for introducing the microwave generated by the microwave generator 15 into the processing apparatus; a wavelength shortening plate 22 for propagating the microwave; and a slot antenna 24 of a thin circular plate shape for introducing the microwave into the dielectric plate 16 from a plurality of slot holes 23. The waveguide 21 incorporates a microwave tuning unit 25 for tuning the microwave generated by the microwave generator 15 on its path from the microwave generator 15 to the wavelength shortening plate 22. Installed in the microwave tuning unit 25 are wavelength control units 26 having paths, the lengths of which are variable. The microwave is tuned by altering the lengths of the paths by the wavelength control units 26. Further, in FIG. 1, a part of an introduction path of the microwave is shown by a dotted line.

The microwave generated by the microwave generator 15 is propagated to the wavelength shortening plate 22 through the waveguide 21 and then is introduced into the dielectric plate 16 from the plurality of slot holes 23 provided at the slot antenna 24. At this time, the dielectric plate 16 vibrates in a vertical direction, i.e., either in a direction of an arrow A in FIG. 1 or in an opposite direction thereto. Here, the recess portions 34 formed on the bottom surface 31 of the dielectric plate 16 have tapered shapes so that they have different thicknesses in a radial direction. Therefore, inside the dielectric plate 16, standing waves in vertical directions are formed at several positions along the radial direction in which the wavelength of the microwave resonates. By the standing waves, an electric field is generated under the dielectric plate 16 inside the processing chamber 12. A plasma igniting condition by a plasma igniting unit, e.g., an application power for generating the plasma, varies depending on the intensity of the electric field. To elaborate, if the intensity of the electric field is high, the application power for generating the plasma decreases, while if the intensity of the electric field is low, the application power for generating the plasma increases.

The intensity of the electric field generated under the dielectric plate 16 by the standing waves as described above has correlation with a gap between the semiconductor substrate W and the dielectric plate 16, i.e., the distance L₁ between the top surface 32 of the semiconductor substrate W held on the holding table 14 and the bottom surface 31 of the dielectric plate 16. Specifically, the electric field intensity has a periodicity. For example, the electric field intensity increases for about every 30 mm of the distance L₁ between the top surface 32 of the semiconductor substrate W and the bottom surface 31 of the dielectric plate 16.

Here, the control unit 20 incorporated in the plasma processing apparatus 11 performs control operations to alter the distance between the holding table 14 and the dielectric plate 16 to a first distance by using the elevating mechanism 18; to drive the plasma igniting unit; then to alter the distance between the holding table 14 and the dielectric plate 16 to a second distance different from the first distance by using the elevating mechanism 18; and to carry out the plasma process on the semiconductor substrate W.

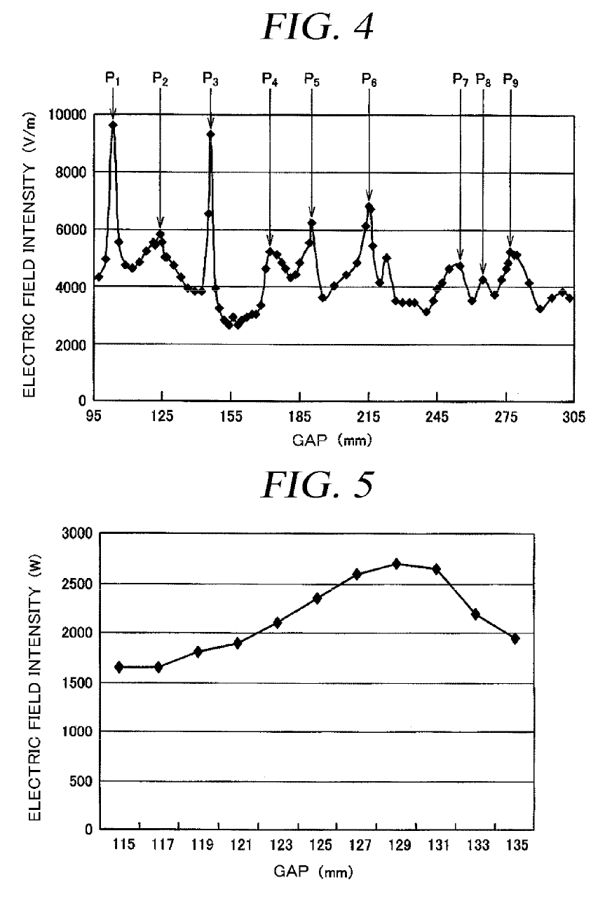

FIG. 4 is a graph showing a relationship between the electric field intensity and a gap in an electromagnetic field simulation. In FIG. 4, a vertical axis represents an electric field intensity (V/M), and a horizontal axis indicates a gap between the top surface 32 of the semiconductor substrate W and the bottom surface 31 of the dielectric plate 16. The electric field intensity is high at positions of about 103 mm, 124 mm, 146 mm, 172 mm, 190 mm, 215 mm, 255 mm, 265 mm and 277 mm indicated by points P₁ to P₉, respectively. Here, periodicity is observed for the relationship between the electric field intensity and the gap. Except for some exceptions, there appear points where the electric field intensity increases in a cycle of about 20 mm.

Further, as for the detailed configuration of the plasma processing apparatus 11, about Ø 200 mm, for instance, is selected as a size of the holding table 14. Further, the variation range of the gap in the plasma processing apparatus 11, i.e., the movement range of the holding table 14 in the vertical direction is selected within a range where the distance from the bottom surface 35 of the processing chamber 12 ranges from about 115 to 135 mm within the range shown in FIG. 4. In such case, the variation range of the holding table 14 is about 20 mm.

Hereinafter, a plasma processing method for the semiconductor substrate W in accordance with an embodiment of the present invention, which is performed by using the plasma processing apparatus 11 configured as described above, will be explained.

First, as described above, the semiconductor substrate W which is a target substrate to be processed is mounted on the holding table 14. Then, the inside of the processing chamber 12 is depressurized to a preset pressure level, and a reactant gas is supplied by the gas shower head 13.

Thereafter, a microwave for plasma excitation is generated by the microwave generator 15 and then is introduced into the processing chamber 12 via the dielectric plate 16. Here, standing waves are formed in the dielectric plate 16 in a vertical direction, so that an electric field is generated under the dielectric plate 16 inside the processing chamber 12.

Subsequently, by moving the holding table 14 up and down by means of the elevating mechanism 18, the distance between the holding table 14 and the dielectric plate 16 is altered. Such variation of the distance is carried out depending on distances selected so as to increase the electric field intensity based on given conditions, for example, the internal pressure of the processing chamber 12, the kind of the reactant gas, the power of the microwave, and the like. This distance is defined as a first distance. In this case, it may be desirable to select the distance indicated by the points P₁ to P₉ at which the electric field intensity increases periodically under the condition illustrated in FIG. 4. In this way, a state in which the electric field intensity under the given conditions is high, i.e., a state in which the application power for generating plasma is low and the plasma is easily likely to be ignited is prepared under the dielectric plate 16.

Afterward, a preset power is applied by the plasma igniting unit to ignite plasma, thereby generating the plasma.

After generating the plasma, a plasma process is performed by altering the distance between the holding table 14 and the dielectric plate 16 so as to allow the semiconductor substrate W held on the holding table 14 to be processed properly based on the given conditions. This distance is defined as a second distance. That is, the plasma process of the semiconductor substrate W is performed by setting the distance between the holding table 14 and the dielectric plate 16 to the second distance suitable for the plasma process.

By setting up the process as described above, the plasma ignition can be carried out by setting the distance between the holding table 14 and the dielectric plate 16 to the first distance. In this way, the distance at which the electric field intensity increases can be selected as the first distance, so that the plasma ignition can be carried out readily. That is, since the plasma ignition can be carried out after increasing the margin of the plasma ignition, plasma ignition property can be improved. Moreover, in the plasma process of the semiconductor substrate W, the distance between the holding table 14 and the dielectric plate 16 is set to the second distance, so that the plasma process of the semiconductor substrate W can be performed after selecting the appropriate distance for the plasma process. Accordingly, the plasma process can be carried out properly. As a result, it becomes possible to ameliorate the plasma ignition property and carry out the plasma process appropriately.

Below, plasma ignition efficiency is shown in Table 1.

TABLE 1

| Gap Setting | Microwave power | Microwave power |
|---|---|---|
| Value (mm) | 1700 W | 1700 W |
| (Actual gap) | (First time) | (Second time) |
| 17 (115) | ◯ | ◯ |
| 19 (117) | ◯ | ◯ |
| 21 (119) | X | ◯ |
| 23 (121) | ◯ | X |
| 25 (123) | X | X |
| 27 (125) | X | X |
| 29 (127) | X | X |
| 31 (129) | X | X |
| 33 (131) | X | X |
| 35 (133) | ◯ | ◯ |
| 37 (135) | ◯ | ◯ |

Table 1 shows success or failure in plasma ignition when the gap was varied while the microwave power applied for the plasma ignition was set to about 1700 W. As for conditions for the evaluation test shown in Table 1, a pressure was set to be about 20 mTorr; the reactant gas was set to “CF₄/O₂=105/9 sccm”, respectively; and a SiO₂ dummy wafer was employed. In Table 1, the mark O stands for a success in plasma ignition, whereas the mark X indicates a failure in plasma ignition. Further, if plasma was not ignited within 5 seconds, it was regarded as failure. In addition, the first time in Table 1 indicates an experiment in which the gap was increased by about 2 mm from about 115 mm to 135 mm, and the second time indicates an experiment in which the gap was narrowed by about 2 mm from about 135 mm to 115 mm. As can be seen from Table 1, plasma ignition succeeds in all of the cases where the gap is about 115 mm, 117 mm, 133 mm and 135 mm. Accordingly, during the plasma ignition, it is desirable to select these gap values as the first distance.

FIG. 5 is a graph showing a relationship between the gap and the microwave power necessary for the plasma ignition. In FIG. 5, a vertical axis represents a microwave power (W), while a horizontal axis indicates a gap (mm). Further, values in FIG. 5 are specified in Table 2.

TABLE 2

| Gap Setting Value (mm) | |
|---|---|
| (Actual gap) | Microwave Power |
| 17 (115) | 1650 |
| 19 (117) | 1650 |
| 21 (119) | 1800 |
| 23 (121) | 1900 |
| 25 (123) | 2100 |
| 27 (125) | 2350 |
| 29 (127) | 2600 |
| 31 (129) | 2700 |
| 33 (131) | 2650 |
| 35 (133) | 2200 |
| 37 (135) | 1950 |

As can be seen from FIG. 5 and Table 2, when the gap is 115 mm or 117 mm, the microwave power necessary for the plasma ignition is relatively small as about 1650 W, and it gradually increases until the gap reaches 129 mm. Meanwhile, if the gap becomes greater than 129 mm, the microwave power necessary for the plasma ignition gradually decreases. As such, since the electric field intensity generated by the standing waves has periodicity depending on the preset condition, it is possible to ignite plasma after selecting a gap value at which the necessary microwave power is reduced.

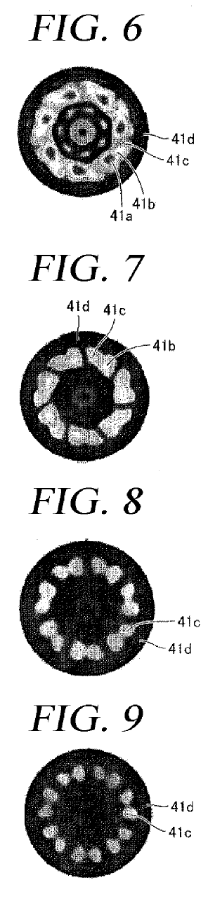

Further, the electric field intensity greatly changes for a gap difference of about 1 mm. FIG. 6 presents a schematic diagram illustrating the state of the electric field intensity under the dielectric plate 16 when the gap is set to about 145 mm. Further, FIG. 7 sets forth a schematic diagram illustrating the state of the electric field intensity under the dielectric plate 16 when the gap is set to about 144 mm, and FIG. 8 is a schematic diagram illustrating the stat of the electric field intensity under the dielectric plate 16 when the gap is set to about 142 mm. Further, FIG. 9 provides a schematic diagram illustrating the state of the electric field intensity under the dielectric plate 16 when the gap is set to about 140 mm. Differences in regions 41a to 41d shown in FIGS. 6 to 9 indicate differences in the height of the electric field intensity. The electric field intensity decreases in the order of the regions 41a, 41b, 41c and 41d. That is, the electric field intensity is highest in the region 41a while it is lowest in the region 41d. Referring to FIGS. 6 to 9, though the gaps are different only by several millimeters, the electric field intensities become greatly different. In view of this, it is required to manage the gap precisely. Further, the maximum electric field intensity is about 9000 V/m, about 6300 V/m, about 5000 V/m and about 4300 V/m when the gap is set to about 145 mm, 144 mm, 142 mm and 140 mm, respectively.

Here, when using a gas having dissociation property is used as the reactant gas necessary for the plasma process, it is desirable to make the second distance shorter than the first distance. That is, after generating the plasma by the plasma ignition, the gap between the holding table 14 and the dielectric plate 16 is narrowed, as illustrated in FIG. 2. As for the reactant gas having the dissociation property, the time period (residence time) during which the reactant gas can stay in the processing chamber 12 without being dissociated therein is short. The reduction of the gap is intended to suppress generation of by-products by the dissociation, thereby allowing the plasma process to be carried out properly.

For example, when C₄F₄ is selected as the reactant gas having the dissociation property, the C₄F₄ would be dissociated if it stays in the processing chamber 12 for a long time, resulting in generation of C₂F₄ in addition to CF₃, CF₂, CF, or the like. If such by-products are generated, there is a likelihood that etching selectivity for the semiconductor substrate W in the plasma process would be changed, for example, thus resulting in failure to carry out the plasma process properly. Further, the residence time of the reactant gas is calculated based on (pressure×volume)/(gas flow rate), and the dissociation degree of the reactant gas is calculated based on (residence time)×(electron density)×(electron temperature). As an example, etching of an oxide-based film of the semiconductor substrate W is performed by using the reactant gas having the dissociation property.

Further, when using a reactant gas not having dissociation property, it is desirable to make the second distance longer than the first distance. That is, after generating the plasma by the plasma ignition, the gap between the holding table 14 and the dielectric plate 16 is increased, as illustrated in FIG. 3. In case of the reactant gas not having the dissociation property, there occurs no cases that the reactant gas would be dissociated and by-products resulted from the dissociation would impede the plasma process. In such case, by enlarging the gap to increase the distance from the dielectric plate 16 and thereby performing the plasma process in a region having further improved plasma uniformity, the plasma process can be performed properly. The reactant gas not having the dissociation property may be, for instance, CF or the like, and as an example, etching of a polysilicon-based film of the semiconductor substrate W is performed by using the CF gas as the reactant gas.

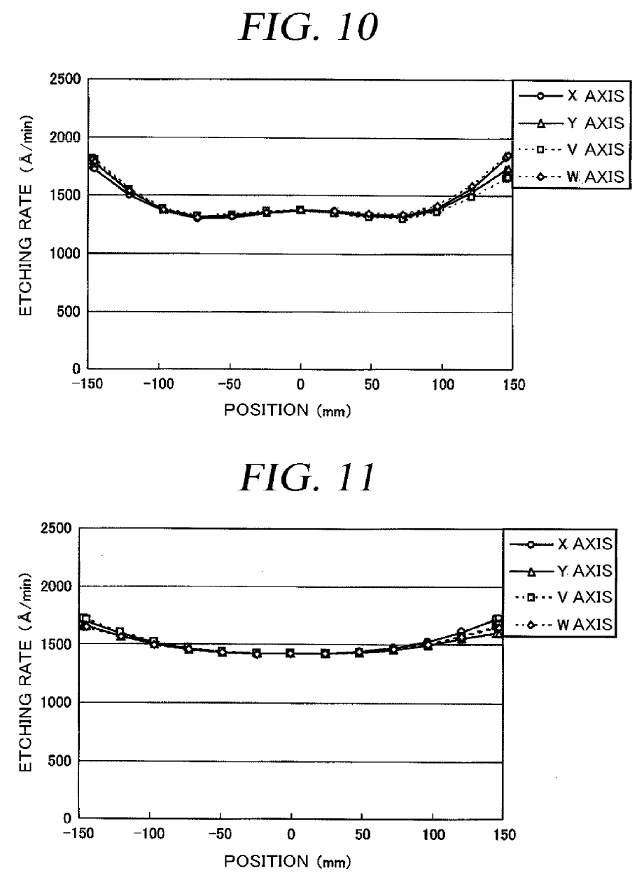

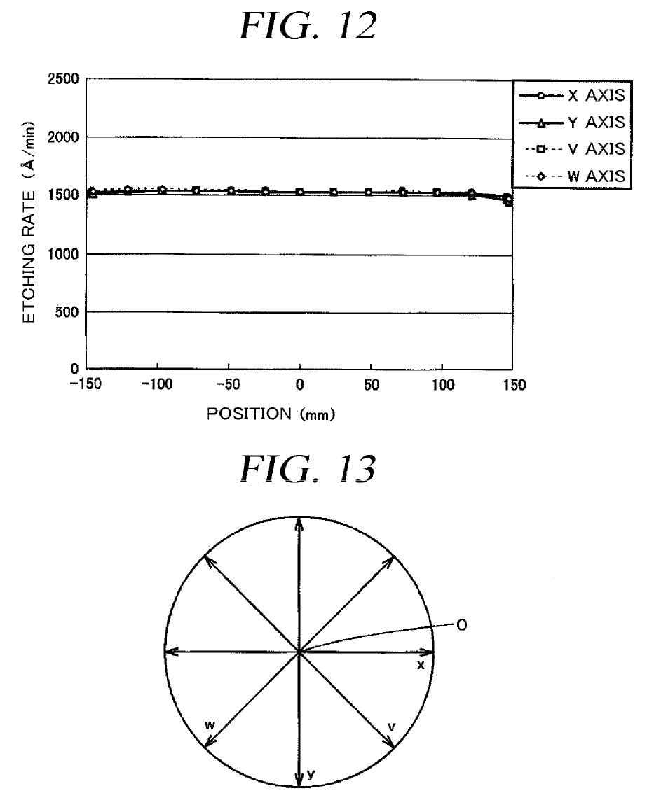

Here, a relationship between the gap and an etching rate is explained. FIG. 10 is a graph showing an etching rate on the semiconductor substrate W when the gap is set to about 135 mm. FIG. 11 sets forth a graph showing an etching rate on the semiconductor substrate W when the gap is set to about 205 mm. FIG. 12 depicts a graph showing an etching rate on the semiconductor substrate W when the gap is set to about 245 mm. In each of FIGS. 10 to 12, a vertical axis represents an etching rate (Å/min), and a horizontal axis indicates a position. FIG. 13 is a diagram showing measurement directions of etching rates in FIGS. 10 to 12. In FIG. 13, x, y, v and w axes are shown. Further, the semiconductor substrate W illustrated in FIG. 13 has a size of about Ø 300 mm with respect to an origin 0.

Referring to FIGS. 10 to 13, the etching rate shows an approximately W-shaped distribution pattern when the gap is about 135 mm (See FIG. 10). To elaborate, etching rates at central portions are slightly higher than those at peripheral portions thereof, and etching rates at edge portions are very high. When the gap is about 205 mm, the etching rate does not have the approximately W-shaped distribution pattern, and the etching rate is more uniform at each position than in case that the gap is set to about 135 mm, but the etching rate is gradually high as the positions are moving from the central portions to the edge portions (see FIG. 11). In contrast, in case that the gap is set to about 245 mm, the etching rate is substantially uniform across the entire in-surface region including the central portions and the edge portions (see FIG. 12). As described, the etching rate gets uniformed as the gap increases. Accordingly, by performing the plasma process of the semiconductor substrate W under the condition that the etching rate is maintained uniformly, the plasma process can be performed properly, i.e., with the uniform etching rate in both the central and edge portions.

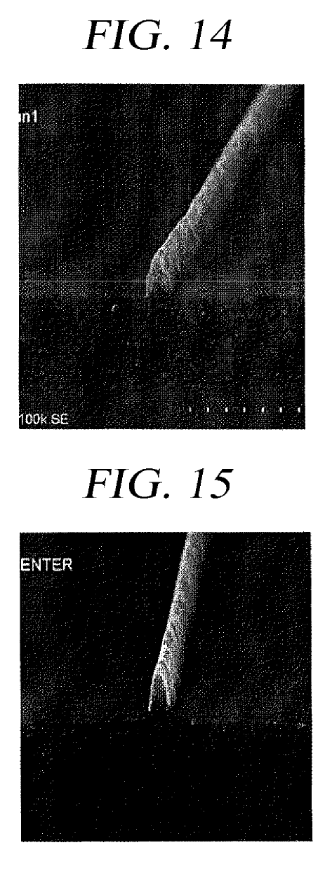

Here, shown in electronographies of FIGS. 14 and 15 are parts of the states of the semiconductor substrate W after an etching process of the semiconductor substrate W is performed while varying the gap. FIGS. 14 and 15 illustrate cases where the gap is set to about 135 mm and 245 mm, respectively. Referring to FIGS. 14 and 15, it can be seen that when performing the etching process by setting the gap to about 245 mm, the end portion of a protrusion is in a good shape, which implies the etching rate is uniform. On the other hand, when performing the etching process by setting the gap to about 135 mm, the shape is spoiled, which means the etching rate is non-uniform.

Further, in the above-described embodiment, though the distance between the holding table and the dielectric plate is described to be varied by moving the holding table for holding the semiconductor substrate W thereon up and down, the present invention is not limited thereto. For example, the distance between the holding table and the dielectric plate can be altered by moving the dielectric plate up and down. Moreover, it may be also possible to change the distance between the holding table and the dielectric plate by setting up configuration in which both the holding table and the dielectric plate are movable up and down.

Furthermore, though the above-mentioned embodiment has been described for the case of performing the etching process by the plasma, the present invention is not limited thereto, but can be applied to a plasma CVD process, or the like.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A plasma processing apparatus comprising:
a processing chamber for performing therein a plasma process on a target substrate to be processed;
a reactant gas supply unit for supplying a reactant gas for the plasma process into the processing chamber;
a holding table disposed in the processing chamber, for holding thereon the target substrate;
a microwave generator for generating a microwave for plasma excitation;
a dielectric plate disposed at a position facing the holding table, for introducing the microwave into the processing chamber; and
a control unit for performing control operations to alter a distance between the holding table and the dielectric plate to a first distance, to drive a plasma igniting unit, to alter the distance between the holding table and the dielectric plate to a second distance different from the first distance, and to carry out the plasma process on the target substrate.

2. The plasma processing apparatus of claim 1, wherein the control unit includes an elevating mechanism for altering the distance between the holding table and the dielectric plate by moving the holding table up and down.

3. The plasma processing apparatus of claim 1, wherein the control unit varies the first distance based on periodicity of a standing wave formed in the dielectric plate by the introduction of the microwave.

4. The plasma processing apparatus of claim 1, wherein the reactant gas supply unit supplies the reactant gas having dissociation property, and the control unit makes the second distance shorter than the first distance.

5. The plasma processing apparatus of claim 4, wherein the plasma process performed on the target substrate by the control unit is an etching process for an oxide-based film.

6. The plasma processing apparatus of claim 1, wherein the reactant gas supply unit supplies the reactant gas not having dissociation property, and the control unit makes the second distance longer than the first distance.

7. The plasma processing apparatus of claim 6, wherein the plasma process performed on the target substrate by the control unit is an etching process for a polysilicon-based film.

8. A plasma processing method for performing a plasma process on a target substrate to be processed, the method comprising:
holding the target substrate on a holding table installed in a processing chamber;
generating a microwave for plasma excitation;
generating an electric field in the processing chamber by introducing the microwave into the processing chamber via a dielectric plate disposed at a position facing the holding table;
generating plasma in the processing chamber by igniting the plasma in a state where a distance between the holding table and the dielectric plate is set to a first distance and an electric field is generated in the processing chamber; and
setting the distance between the holding table and the dielectric plate to a second distance different from the first distance after generating the plasma and performing the plasma process on the target substrate.
